(19) United States
(12) Patent Application Publication
(10) Pub. No.: US 2009/0116317 A1
(43) Pub. Date: May 7, 2009

(54) Block repair apparatus and method thereof

(75) Inventor: Saeng Hwan Kim, Suwon-si (KR)

Correspondence Address: COOPER & DUNHAM, LLP, 30 Rockefeller Plaza, 20th Floor, NEW YORK, NY, 10112, US

(73) Assignee: Hynix Semiconductor Inc.

(21) Appl. No.: 12/070,952

(22) Filed: Feb. 22, 2008

(30) Foreign Application Priority Data
Nov. 2, 2007 (KR) 10-2007-0111521

(51) Int. Cl. G11C 29/00; G11C 7/00; G11C 8/00; G11C 17/18

(52) U.S. Cl. 365/200; 365/225.7; 365/230.03; 365/230.06

(57) ABSTRACT

A block repair apparatus includes a plurality of cell blocks, a block repair fuse, a block isolation control unit, and a block repair selector. The block repair fuse outputs a repair signal of the plurality of cell blocks. The block isolation control unit outputs a control signal for activating the plurality of cell blocks or electrically isolating a defective cell block of the plurality of cell blocks, in response to the block repair signal. The block repair selector outputs a block repair selection signal for replacing the defective cell block with another cell block in response to a cell block address signal.

### BACKGROUND

The present disclosure relates to a semiconductor memory device, and more particularly, to a block repair apparatus for a dynamic random access memory (DRAM) cell and a method thereof.

FIG. 1 illustrates a block diagram of a conventional DRAM cell, FIG. 2 illustrates a circuit diagram of a conventional bit line sense amplifier, and FIG. 3 illustrates a circuit diagram of a block isolation control unit in a conventional DRAM.

Referring to FIGS. 1 to 3, since upper and lower cell blocks share a sense amplifier, a bit line isolation (BIS) bearer is usually used in order to reduce bit line load. Also, since bit lines of an unselected block is precharged to a bit line precharge voltage VBLP, a circuit for precharging a bit line to the bit line precharge voltage VBLP is included in each bit line sense amplifier. A BIS of an unselected block should be at a high level such that a bit line is precharged and the BIS should be controlled such that a sense amplifier of a selected block does not affect a bit line of an adjacent block.

FIG. 4 illustrates an electrical short in a conventional DRAM cell and illustrates a short defect between a bit line and a word line, not a cell defect. In this case, the DRAM cell may be repaired by a defective bit line or word line repairing circuit, but current consumption due to an electrical short cannot be prevented. This is because a signal BIS_UP or BIS_DN is always activated for precharging a bit line when a block is not selected. If the current consumption is not great, it does not matter. However, when the current consumption is over the limit of a quiescent current or a VBLP generating apparatus, a faulty product is the result.

The yield rate of a conventional DRAM can be greatly improved by including a redundant cell and replacing a defective cell with the redundant cell. However, when a current consumption due to an electrical short in a cell block is over a critical value, the cell cannot be repaired.

### BRIEF SUMMARY

Various embodiments of the present disclosure are directed to a block repair apparatus for repairing an electrical short by electrically-isolating an entire block and replacing the cell block by a redundant cell block when an electrical short occurs in a cell block and a method thereof.

In an aspect of this disclosure, a block repair apparatus includes a plurality of cell blocks, a block repair fuse configured to output a repair signal of the plurality of cell blocks, a block isolation control unit configured to output a control signal for activating the plurality of cell blocks or electrically isolating a defective cell block of the plurality of cell blocks, in response to the block repair signal, and a block repair selector configured to output a block repair selection signal for replacing the defective cell block with another cell block in response to a cell block address signal.

In another aspect, a block repair apparatus includes a plurality of cell blocks configured to store data, a redundant cell block configured to replace a defective cell block of the plurality of cell blocks, a block repair fuse configured to disable the defective cell block, a block isolation control unit configured to activate the plurality of cell blocks and the redundant cell block and electrically isolate the defective cell block in response to an output signal of the block repair fuse, and a block repair selector configured to output a block repair selection signal for replacing the defective cell block by the redundant cell block in response to a cell block address signal.

In still another aspect, a block repair method includes detecting an electrical short of a specific block of a plurality of cell blocks, using a test mode signal; electrically isolating the defective cell block using a block isolation control unit when the defective cell block is determined to be in the plurality of cell blocks, determining whether a cell block address signal is an address signal of the defective cell block, using a block repair selector when the cell block address signal is input, and replacing the defective cell block by a redundant cell block using the block isolation control unit when the cell block address signal is the address signal of the defective cell block.

### BRIEF DESCRIPTION OF THE DRAWINGS

FIG. 1 illustrates a block diagram of a conventional DRAM cell.

FIG. 2 illustrates a circuit diagram of a conventional bit line sense amplifier.

FIG. 3 illustrates a circuit diagram of a block isolation control unit in a conventional DRAM.

FIG. 4 illustrates an electrical short in a conventional DRAM cell.

FIG. 5 illustrates a block diagram of a block repair apparatus of a DRAM cell according to an exemplary embodiment of the present disclosure.

FIGS. 6 and 7 illustrate a circuit diagram and a schematic diagram of a block repair apparatus according to an exemplary embodiment of the present disclosure.

FIG. 8 illustrates a circuit of a block isolation control unit in the block repair apparatus shown in FIGS. 6 and 7.

FIG. 9A illustrates a graph of a VDD level with respect to a signal Power-b according to the exemplary embodiment of FIGS. 6 and 7.

FIG. 9B illustrates a circuit diagram of a block repair fuse in the block repair apparatus of FIGS. 6 and 7.

FIG. 10 illustrates a circuit diagram of a block repair selector in the block repair apparatus of FIG. 7.

FIG. 11 illustrates a block diagram of a block repair apparatus according to another exemplary embodiment of the present disclosure.

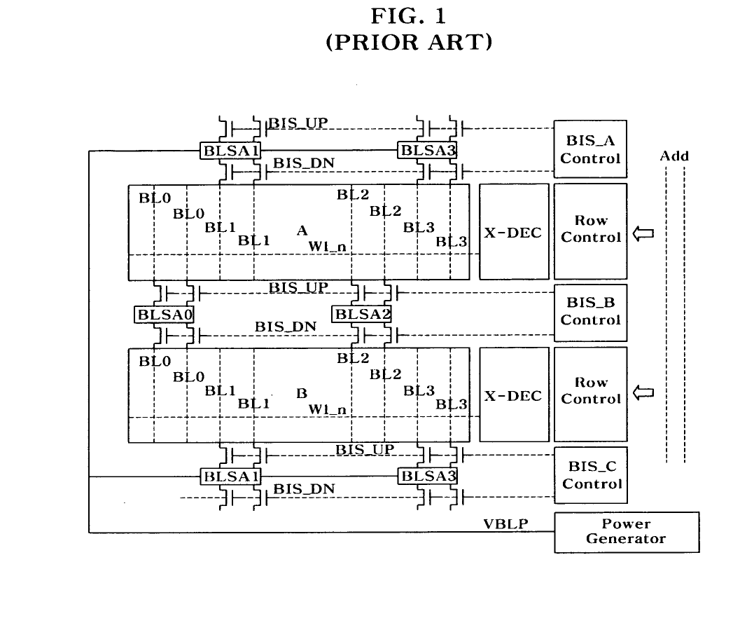

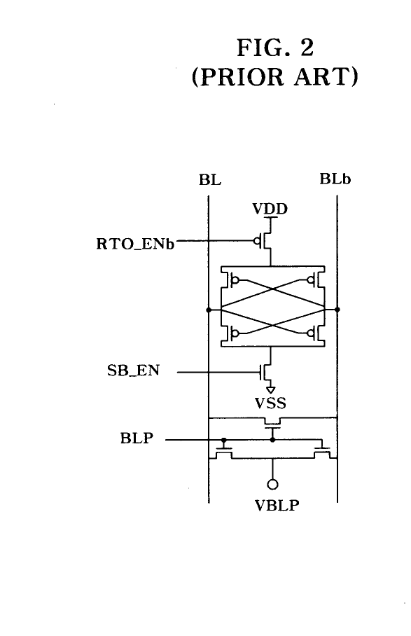

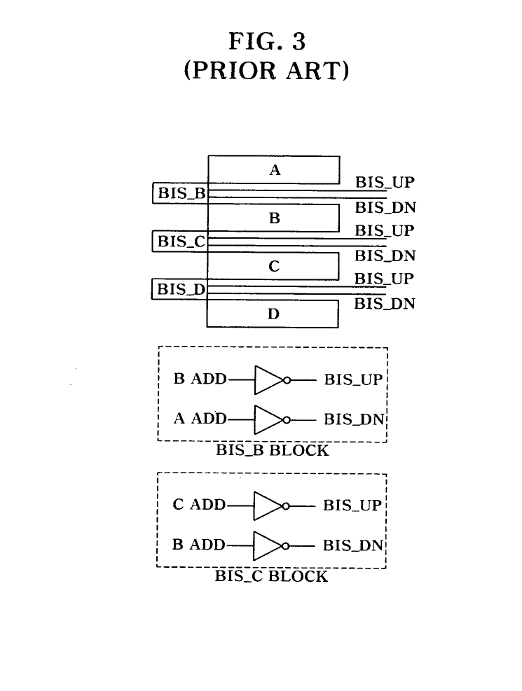

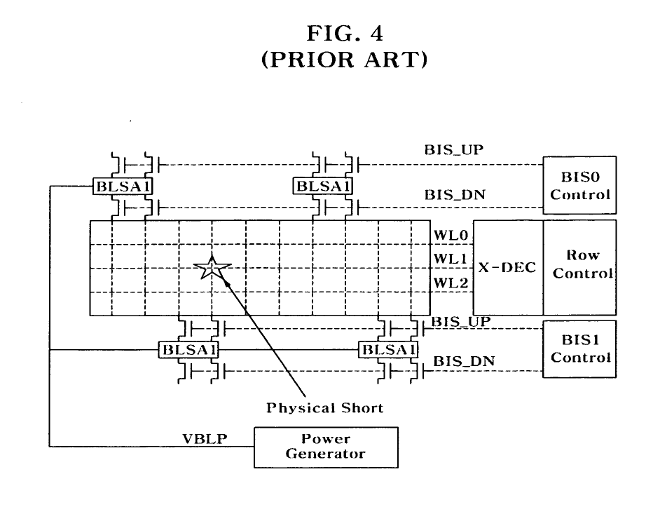

### DESCRIPTION OF EXEMPLARY EMBODIMENTS

Hereinafter, the present invention will be described through examples and exemplary embodiments with reference to the accompanying drawings.

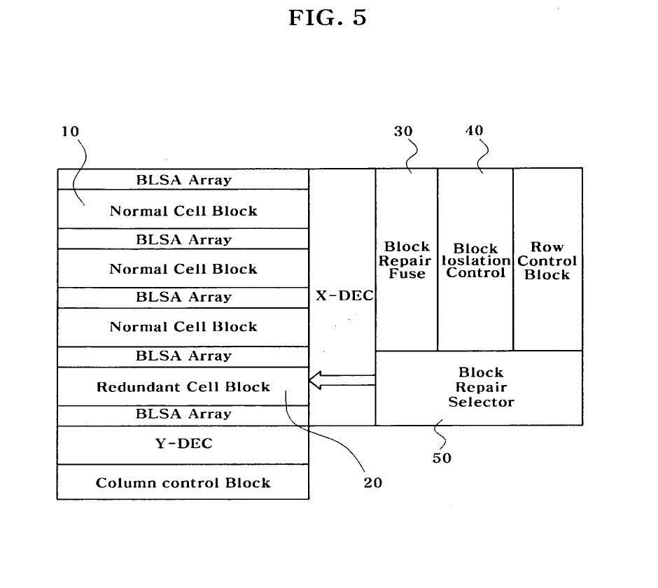

FIG. 5 illustrates a block diagram of a block repair apparatus of a DRAM cell according to an exemplary embodiment of the present disclosure.

Referring to FIG. 5, a redundant cell block 20 replaces a defective cell block of a plurality of cell blocks 10 when an electrical short or a cell defect occurs in the specific block. A block repair fuse 30 outputs a repair signal of the plurality of cell blocks 10. A block isolation control unit 40 outputs a control signal for activating the plurality of cell blocks 10 or electrically isolating a defective cell block of the plurality of cell blocks 10, in response to the block repair signal. A block repair selector 50 outputs a block repair selection signal for replacing the defective cell block with another cell block in response to a cell block address signal.

A sense amplifier array senses a bit line used in a conventional DRAM. X-decoder and Y-decoder blocks select a word line and a bit line, respectively. A row control block and a column control block control rows and columns, respectively.

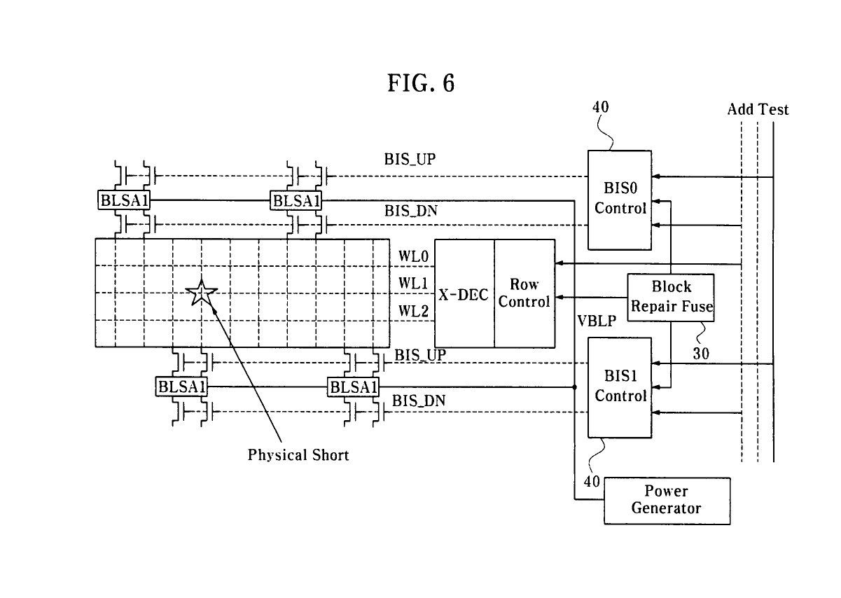

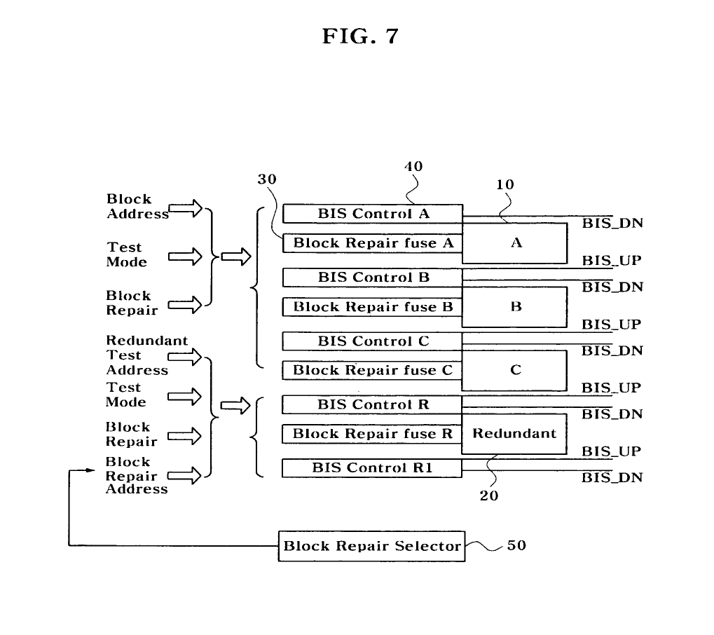

FIGS. 6 and 7 illustrate a circuit diagram and a schematic diagram of a block repair apparatus according to another exemplary embodiment of the present disclosure.

Referring to FIGS. 6 and 7, when a defect such as an electrical short occurs between a bit line and a word line, a defective block is replaced by a redundant cell block 20 and a block repair fuse 30 is cut to disable an X-decoder, a row control block, and the like of the defective block. Next, a block isolation control unit 40 is controlled so as to electrically isolate the defective block.

In FIG. 7, a block address means an aligned block address of each cell block and a block repair means an output of a -fuse that represents whether or not to repair each cell block. When an electrical short occurs, a corresponding block is found. For this, a voltage is supplied to only a selected block, a current is measured, and it is determined whether a short occurs or not by controlling a signal BIS_UP or BIS_DN so as to supply a voltage to only a specific block using a test mode used in a DRAM.

FIG. 8 illustrates a circuit of the block isolation control unit 40.

Referring to FIG. 8, the block isolation control unit 40 includes an operating unit that performs a NOR operation in response to an output signal of the block repair fuse 30, a block address signal, and a test mode signal. Here, a signal BIS_UP or BIS_DN of a redundant cell block is variable depending a replaced block and an output signal of the block repair selector 50 is used as an address of the replaced block.

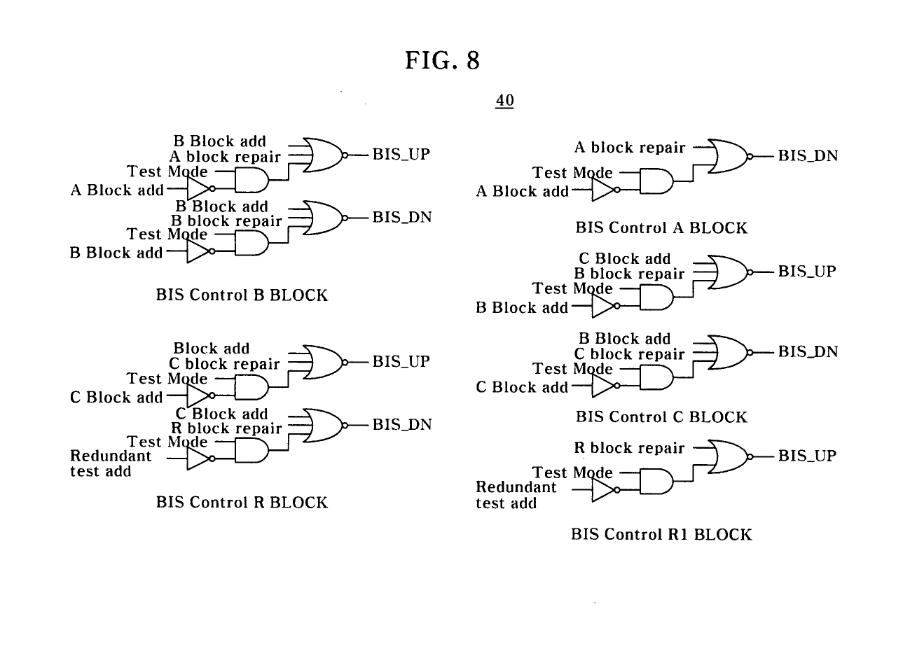

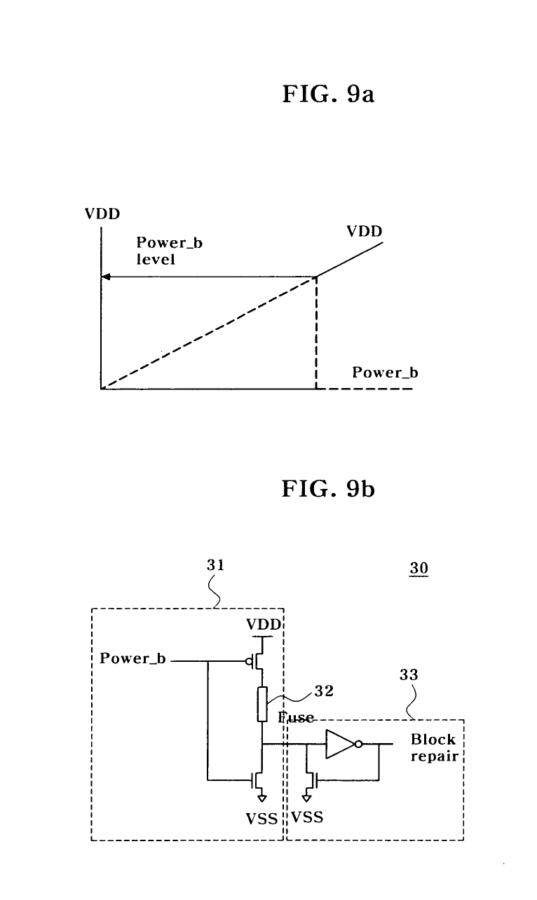

FIG. 9A illustrates a graph of a VDD level with respect to a signal Power_b, and FIG. 9B illustrates a circuit diagram of the block repair fuse unit 30.

Referring to FIGS. 9A and 9B, the block repair fuse 30 includes a driver unit 31 that pulls up and pulls down a node in response to an initialization signal (Power_b), a fuse 32 allows the driver unit 31 to pull down the node in fuse cutting, and a latch unit 33 that latches an output signal of the driver unit 31. The signal Power_b is used for circuit initialization of a DRAM and transits to a low level when a VDD potential reaches a predetermined level.

Therefore, the block repair signal is at a high level unless the fuse is not cut, and becomes a low level when the VDD potential increases. However, the block repair signal is maintained at a high level after fuse cutting.

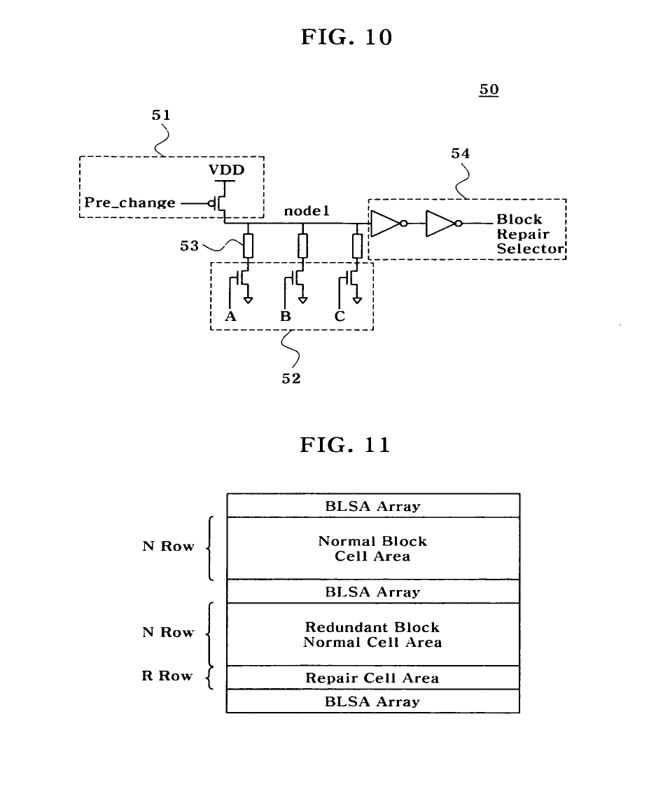

FIG. 10 illustrates a circuit diagram of the block repair selector 50.

Referring to FIG. 10, the block repair selector 50 includes a pull up driver unit 51 that pulls up a node (node 1) in response to a precharge signal (Pre-charge), a pull down driver unit 52 that pull downs a node in response to an address signal (A, B, C) of a cell block, a fuse 53 that allows the node (node 1) to be pulled up in fuse cutting, and a buffer unit 54 that buffers a signal at the node (node 1) and outputs a Block Repair Selector signal.

In the block repair selector 50, a block repair signal is at a high level by application of a precharge signal before a cell block is activated. The block repair signal transits to a low level if a fuse is not cut and a specific cell block is activated through an address signal of a corresponding block, and is maintained at a high level if the fuse is cut. Therefore, it may be determined which block will be replaced through the block repair signal.

In addition, when a defect such as an electrical short does not occurs in any block, a redundant block can be used as a defect repair cell used in a conventional DRAM. When an electrical short defect occurs in a block, the block is replaced by the redundant block and an additional defect can be repaired by a column repair included in a conventional DRAM.

FIG. 11 illustrates a block diagram of a block repair apparatus according to another exemplary embodiment of the present disclosure. Referring to FIG. 11, when a defect occurs in a word line as well as an electrical short in a block, the block cannot be repaired using only a column repair, and thus, a redundant word line is additionally included besides a unit block so as to repair the defective cell block. A repairing method thereof is the same as the method used in a conventional DRAM.

Operation of a block repair apparatus, according to an exemplary embodiment of the present disclosure, will be described with reference to the accompanying drawings.

An electrical short is detected in a specific block of a plurality of cell blocks using a test mode signal. In detail, a voltage is supplied to the specific block using the test mode signal and a current of the corresponding block is measured to determine a short.

When a defective cell block is detected, the defective cell block is electrically isolated using the block isolation control unit 40. In detail, when the block repair fuse 30 outputs a block repair signal due to fuse cutting in response to an initialization signal, the block isolation control unit 40 electrically isolates the defective cell block by cutting off supply of voltage in response to the block repair signal.

Next, when an address signal of a cell block is input, it is determined whether the cell block address signal is an address signal of a defective cell block using the block repair selector 50. In detail, when the block repair selector 50 outputs a block repair selection signal due to fuse cutting in response to the cell block address signal, it is determined whether the cell block address signal is an address signal of the defective cell block depending on activation of the block repair selection signal.

If the cell block address is an address of a defective cell block, the defective cell block is replaced by a redundant cell block 20 using the block isolation control unit 40. In detail, the block isolation control unit 40 supplies a voltage to the redundant cell block instead of the defective cell block in response to an output signal of the block repair selector 50.

According to the present invention, when an electrical short occurs in a cell block, an entire block can be electrically isolated and replaced by a redundant cell block, thereby reducing a current consumption and improve the yield rate.

While the present invention has been described with respect to examples and exemplary embodiments, it will be apparent to those skilled in the art that various changes and modifications may be made without departing from the spirit and scope of the disclosure and the following claims. For example, elements and/or features of different examples and illustrative embodiments may be combined with each other and/or substituted for each other within the scope of this disclosure and appended claims.

The present disclosure claims priority to Korean patent application number 10-2007-0111521, filed on Nov. 2, 2007, the entire contents of which are incorporated herein by reference.

What is claimed is:

1. A block repair apparatus, comprising:
a plurality of cell blocks;
a block repair fuse configured to output a repair signal of the plurality of cell blocks;
a block isolation control unit configured to output a control signal for activating the plurality of cell blocks or electrically isolating a defective cell block of the plurality of cell blocks, in response to the block repair signal; and
a block repair selector configured to output a block repair selection signal for replacing the defective cell block with another cell block in response to a cell block address signal.

2. The block repair apparatus of claim 1, wherein the block repair fuse comprises:
a driver unit configured to pull up and pull down a node in response to an initialization signal;
a fuse configured to allow the driver unit to pull down the node in fuse cutting; and
a latch unit configured to latch an output signal of the driver unit.

3. The block repair apparatus of claim 2, wherein the initialization signal transits to a low level when an external voltage potential becomes a predetermined logic level.

4. The block repair apparatus of claim 1, wherein the block isolation control unit comprises an operating unit that performs a NOR operation in response to an output signal of the block repair fuse, a block address signal, and a test mode signal.

5. The block repair apparatus of claim 4, wherein the test mode signal is a signal configured to activate only a selected block, for determining an electrical short of a specific block.

6. The block repair apparatus of claim 1, wherein the block repair selector comprises:
a pull up driver unit configured to pull up a node in response to a precharge signal;
a pull down driver unit configured to pull down the node in response to the cell block address signal;
a second fuse configured to allow the node to be pulled up in fuse cutting; and
a buffer unit configured to buffer a signal at the node.

7. The block repair apparatus of claim 1, further comprising:
a sense amplifier array configured to sense a bit line;
X-decoder and Y-decoder blocks configured to select a word line and a bit line, respectively; and
a row control block and a column control block configured to control rows and columns, respectively.

8. A block repair apparatus comprising:
a plurality of cell blocks configured to store data;
a redundant cell block configured to replace a defective cell block of the plurality of cell blocks;
a block repair fuse configured to disable the defective cell block;
a block isolation control unit configured to activate the plurality of cell blocks and the redundant cell block and electrically isolate the defective cell block, in response to an output signal of the block repair fuse; and
a block repair selector configured to output a block repair selection signal for replacing the defective cell block by the redundant cell block in response to a cell block address signal.

9. The block repair apparatus of claim 8, wherein the block repair fuse comprises:
a driver unit configured to pull up and pull down a node in response to an initialization signal;
a fuse configured to allow the driver unit to pull down the node in fuse-cutting; and
a latch unit configured to latch an output signal of the driver unit.

10. The block repair apparatus of claim 9, wherein the initialization signal transits to a low level when an external voltage potential becomes a predetermined logic level.

11. The block repair apparatus of claim 8, wherein the block isolation control unit comprises an operating unit that performs a NOR operation in response to an output signal of the block repair fuse, a block address signal, and a test mode signal.

12. The block repair apparatus of claim 11, wherein the test mode signal is a signal configured to activate only a selected block, for determining an electrical short of a specific block.

13. The block repair apparatus of claim 8, wherein the block repair selector comprises:
a pull up driver unit configured to pull up a node in response to a precharge signal;
a pull down driver unit configured to pull down the node in response to the cell block address signal;
a second fuse configured to allow the node to be pulled up in fuse cutting; and
a buffer unit configured to buffer a signal at the node.

14. The block repair apparatus of claim 8, further comprising:
a sense amplifier array configured to sense a bit line;
X-decoder and Y-decoder blocks configured to select a word line and a bit line, respectively; and
a row control block and a column control block configured to control rows and columns, respectively.

15. A block repair method, comprising:
detecting an electrical short of a specific block of a plurality of cell blocks using a test mode signal for determining a defective cell block;
electrically isolating the defective cell block using a block isolation control unit when the defective cell block is determined tome in the plurality of cell blocks;
determining whether a cell block address signal is an address signal of the defective cell block, using a block repair selector when the cell block address signal is input; and
replacing the defective cell block by a redundant cell block using the block isolation control unit when the cell block address signal is the address signal of the defective cell block.

16. The block repair method of claim 15, wherein the detecting of an electrical short of the specific block comprises:
supplying a voltage to only the specific block using the test mode signal; and
measuring a current of the specific block to detect the electrical short.

17. The block repair method of claim 15, wherein the electrically isolating of the defective cell block comprises: outputting, at a block repair fuse, a block repair signal due to fuse cutting in response to an initialization signal; and
cutting off, at the block isolation control unit, supply of a voltage to the defective cell block in response to the block repair signal.

18. The block repair method of claim 15, wherein the determining whether the address signal of the cell block is an address signal of the defective cell block comprises: outputting, at the block repair selector, a block repair selection signal due to fuse cutting in response to the cell block address signal.
and determining whether the cell block address signal is the address signal of the defective cell block depending on whether the block repair selection signal is activated.

19. The block repair method of claim 15, wherein the replacing of the defective cell block comprises supplying, at the block isolation control unit, a voltage to the redundant cell block instead of the defective cell block in response to an output signal of the block repair selector.
